(19) United States
(12) Patent Application Publication
(10) Pub. No.: US 2007/0252637 A1
(43) Pub. Date: Nov. 1, 2007

(54) Power switching circuit and liquid crystal display using same

(75) Inventors: Tong Zhou, Shenzhen (CN); Jia-Hui Tu, Shenzhen (CN); Kun Le, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/796,795

(22) Filed: Apr. 30, 2007

(30) Foreign Application Priority Data
Apr. 28, 2006 (TW) 95115278

(51) Int. Cl. H03K 17/687

(52) U.S. Cl. 327/432

(57) ABSTRACT

An exemplary power switching circuit (20) includes a control signal input terminal (210) which is configured for receiving a control signal; an output terminal (220) configured to be connected to a load circuit with capacitance; a direct current (DC) power supply (230); a first switching transistor (240) including a control electrode connected to the control signal input terminal, a first current conducting electrode, and a grounded second current conducting electrode; a second switching transistor (250) including a control electrode connected to the first current conducting electrode of the first switching transistor, a first current conducting electrode connected to the DC power supply, and a second current conducting electrode connected to the output terminal; and a third switching transistor (260) including a control electrode connected to the control signal input terminal, a first current conducting electrode connected to the output terminal, and a grounded second current conducting electrode.

### FIELD OF THE INVENTION

The present invention relates to power switching circuits and liquid crystal displays (LCDs) using power switching circuits, and particularly to a power switching circuit employing one direct current (DC) power supply.

### GENERAL BACKGROUND

An LCD has the advantages of portability, low power consumption, and low radiation, and has been widely used in various portable information products such as notebooks, personal digital assistants (PDAs), video cameras and the like. Furthermore, the LCD is considered by many to have the potential to completely replace CRT (cathode ray tube) monitors and televisions.

A typical LCD includes an LCD panel. The LCD panel includes a multiplicity of pixels, each having a capacitance. When a power supply provides an operation voltage to the LCD and then the power supply is turned off, the operation voltage does not immediately decrease. For example, when a power supply voltage of 5V is turned off, a decrease to a residual voltage 0.4 V takes about 20 seconds. If the power supply is turned on again quickly before the residual voltage in the power supply has decreased to a predetermined voltage, this causes an operational error in the LCD. To prevent such operational error, a power switching circuit is provided in the LCD to remove the residual voltage.

FIG. 3 is a diagram of a typical power switching circuit 10 used in an LCD. The power switching circuit 10 includes a control signal input terminal 110 which is configured for receiving control signals, an output terminal 120 connected to the LCD, a twelve volt direct current (DC) power supply 130, a five volt DC power supply 140 functioning as a main power source of the LCD, a first negative-positive-negative (NPN) transistor 150, a second NPN transistor 170, an n-channel enhancement mode metal-oxide-semiconductor (NMOS) transistor 160, a first resistor 155, a second resistor 156, a third resistor 165, a fourth resistor 175, and a fifth resistor 176.

The first NPN transistor 150 includes a base electrode “b” connected to the control signal input terminal 110 via the first resistor 155, an emitter electrode “e” connected to the base electrode “b”0 via the second resistor 156 and also connected to ground, and a collector electrode “c” connected to the 12V DC power supply 130 via the third resistor 165.

The second NPN transistor 170 includes a base electrode “b” connected to the control signal input terminal 110 via the fourth resistor 175, an emitter electrode “e” connected to ground, and a collector electrode “c” connected to the output terminal 120 via the fifth resistor 176.

The NMOS transistor 160 includes a gate electrode “G” connected to the collector electrode “c” of the first NPN transistor 150, a source electrode “S” connected to the output terminal 120, and a drain electrode “D” connected to the 5V DC power supply 140.

In order to apply a 5V voltage from the 5V DC power supply 140 to the output terminal 120, a first control signal such as a low level 0V voltage is provided to the control signal input terminal 110 by an external circuit (not shown). Thus the first NPN transistor 150 and the second NPN transistor 170 are switched off. A 12V voltage from the 12V DC power supply 130 is applied to the gate electrode “G” of the NMOS transistor 160 via the third resistor 165. Thus the NMOS transistor 160 is switched on, and the 5V voltage from the 5V DC power supply 140 is applied to the output terminal 120 via the activated NMOS transistor 160.

In order to suspend the supply of the 5V voltage from the 5V DC power supply 140 to the output terminal 120, a second control signal such as a high level 5V voltage is provided to the control signal input terminal 110 by the external circuit. Thus the first NPN transistor 150 and the second NPN transistor 170 are switched on. The gate electrode “G” of the NMOS transistor 160 is connected to ground via the activated first NPN transistor 150, so that the NMOS transistor 160 is switched off. Thus, the 5V voltage from the 5V DC power supply 140 cannot be provided to the output terminal 120. Electric charges stored in an LCD (not shown) which is connected to the output terminal 120 can be discharged quickly through the activated second NPN transistor 170.

Because the power switching circuit 10 includes the two power supplies 130, 140, the layout of the power switching circuit 10 is rather complicated.

It is desired to provide a new power switching circuit used in an LCD which can overcome the above-described deficiencies.

### SUMMARY

In one preferred embodiment, a power switching circuit includes a control signal input terminal which is configured for receiving a control signal; an output terminal configured to be connected to a load circuit; a direct current (DC) power supply; a first switching transistor including a control electrode connected to the control signal input terminal, a first current conducting electrode, and a second current conducting electrode connected to ground; a second switching transistor including a control electrode connected to the first current conducting electrode of the first switching transistor, a first current conducting electrode connected to the DC power supply, and a second current conducting electrode connected to the output terminal; and a third switching transistor including a control electrode connected to the control signal input terminal, a first current conducting electrode connected to the output terminal, and a second current conducting electrode connected to ground.

Other novel features and advantages will become more apparent from the following detailed description when taken in conjunction with the accompanying drawings.

### BRIEF DESCRIPTION OF THE DRAWINGS

FIG. 1 is a diagram of a power switching circuit according to a first embodiment of the present invention, the power switching circuit being typically used in an LCD.

FIG. 2 is a diagram of a power switching circuit according to a second embodiment of the present invention, the power switching circuit being typically used in an LCD.

FIG. 3 is a diagram of a conventional power switching circuit used in an LCD.

### DETAILED DESCRIPTION OF PREFERRED EMBODIMENTS

Reference will now be made to the drawings to describe the present invention in detail.

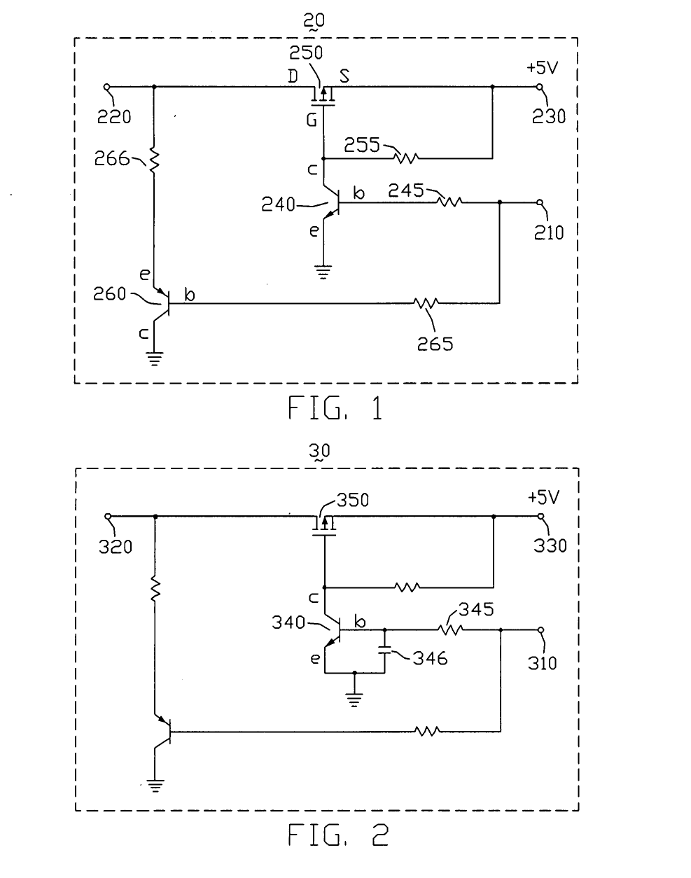

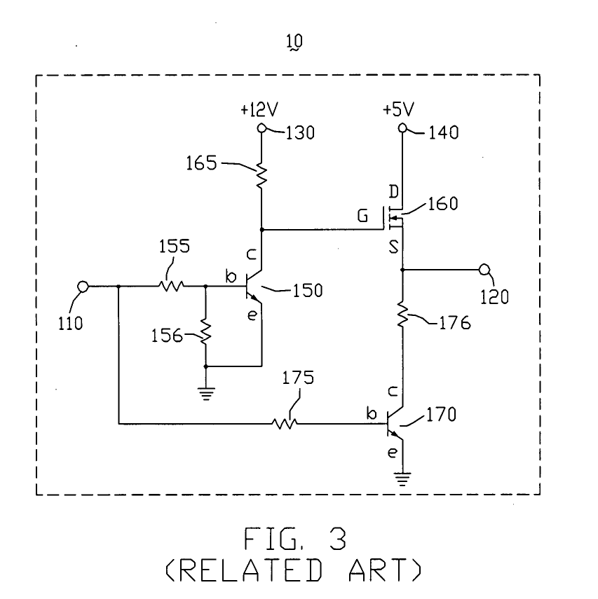

FIG. 1 is a diagram of a power switching circuit 20 according to a first embodiment of the present invention, the power switching circuit being typically used in an LCD. The power switching circuit 20 includes a control signal input terminal 210 which is configured for receiving a control signal, an output terminal 220 configured for connecting to a load circuit (not shown) such as an LCD, a five volt DC power supply 230 functioning as a main power source of the load circuit, an NPN transistor 240, a positive-negative-positive (PNP) transistor 260, a p-channel enhancement mode metal-oxide-semiconductor (PMOS) transistor 250, a first current limiting resistor 265, a second current limiting resistor 245, a bias resistor 255, and a discharging resistor 266.

The NPN transistor 240 includes a base electrode “b” connected to the control signal input terminal 210 via the second current limiting resistor 245, a emitter electrode “e” connected to ground, and a collector electrode “c” connected to the DC power supply 230 via the bias resistor 255.

The PNP transistor 260 includes a base electrode “b” connected to the control signal input terminal 210 via the first current limiting resistor 265, a collector electrode “c” connected to ground, and an emitter electrode “e” connected to the output terminal 220 via the discharging resistor 266.

The PMOS transistor 250 includes a gate electrode “G” connected to the collector electrode “c” of the NPN transistor 240, a source electrode “S” connected to the DC power supply 230, and a drain electrode “D” connected to the output terminal 220.

In order to apply the 5V voltage from the DC power supply 230 to the output terminal 220, a first control signal such as a high level 5V voltage is provided to the control signal input terminal 210 by an external circuit (not shown). Thus the NPN transistor 240 is switched on and the PNP transistor 260 is switched off. The gate electrode “G” of the PMOS transistor 250 is connected to ground via the activated NPN transistor 240. A voltage difference between the gate electrode “G” and the source electrode “S” of the PMOS transistor 250 is approximately equal to −5V, thus the PMOS transistor 250 is switched on. Accordingly, the 5V voltage from the DC power supply 230 is provided to the output terminal 220 via the activated PMOS transistor 250.

In order to suspend the supply of the 5V voltage from the DC power supply 230 to the output terminal 220, a second control signal such as a low level 0V voltage is provided to the control signal input terminal 210 by the external circuit. Thus the NPN transistor 240 is switched off and the PNP transistor 260 is switched on. The gate electrode “G” of the PMOS transistor 250 is connected to the DC power supply 230. A voltage difference between the gate electrode “G” and the source electrode “S” of the PMOS transistor 250 is approximately equal to 0V, thus the PMOS transistor 250 is switched off. Therefore, the 5V voltage from the DC power supply 230 cannot be provided to the output terminal 220. Electric charges stored in the load circuit which is connected to the output terminal 220 can be quickly discharged through the activated PNP transistor 260.

Because the power switching circuit 20 includes only the one DC power supply 230, the layout of the power switching circuit 20 is relatively simple.

FIG. 2 is a diagram of a power switching circuit 30 according to a second embodiment of the present invention, the power switching circuit being typically used in an LCD. A characteristic of the power switching circuit 30 different from the power switching circuit 20 is that the power switching circuit 30 further includes a charging capacitor 346 connected between a base electrode “b” and an emitter electrode “e” of an NPN transistor 340. The NPN transistor 340 and the charging capacitor 346 cooperatively function as a counterpart of the NPN transistor 240 of the power switching circuit 20. A current limiting resistor 345 is connected to the base electrode “b” of the NPN transistor 340. Typically, the current limiting resistor 345 and the charging capacitor 346 are constituted in an integrated circuit.

When a control signal provided to a control signal input terminal 310 changes from a low level 0V voltage to a high level 5V voltage, the integrated circuit can prevent the NPN transistor 340 and a PMOS transistor 350 from being switched on too quickly. Thus a rush of current of a load circuit generated when a 5V voltage from a five volt DC power supply 330 is applied to an output terminal 320 can be reduced or even eliminated.

In various alternative embodiments, each of the NPN transistors 240, 340 can be replaced by an NMOS transistor, the PNP transistor 260 can be replaced by a PMOS transistor, and each of the PMOS transistors 250, 350 can be replaced by a PNP transistor.

It is to be further understood that even though numerous characteristics and advantages of preferred and exemplary embodiments have been set out in the foregoing description, together with details of the structures and functions of the embodiments, the disclosure is illustrative only; and that changes may be made in detail, especially in matters of arrangement of parts within the principles of present invention to the full extent indicated by the broad general meaning of the terms in which the appended claims are expressed.

What is claimed is:

1. A power switching circuit comprising:
a control signal input terminal configured for receiving a control signal;
an output terminal configured to be connected to a load circuit;
a direct current (DC) power supply;
a first switching transistor comprising a control electrode connected to the control signal input terminal, a first current conducting electrode, and a second current conducting electrode connected to ground;
a second switching transistor comprising a control electrode connected to the first current conducting electrode of the first switching transistor, a first current conducting electrode connected to the DC power supply, and a second current conducting electrode connected to the output terminal; and
a third switching transistor comprising a control electrode connected to the control signal input terminal, a first current conducting electrode connected to the output terminal, and a second current conducting electrode connected to ground.

2. The power switching circuit as claimed in claim 1, further comprising a first current limiting resistor connected between the control electrode of the third switching transistor and the control signal input terminal.

3. The power switching circuit as claimed in claim 2, further comprising a bias resistor connected between the control electrode and first current conducting electrode of the second switching transistor.

4. The power switching circuit as claimed in claim 3, further comprising a second current limiting resistor connected between the control electrode of the first switching transistor and the control signal input terminal.

5. The power switching circuit as claimed in claim 4, further comprising a charging capacitor connected between the control electrode and second current conducting electrode of the second switching transistor.

6. The power switching circuit as claimed in claim 1, wherein the first switching transistor is an NPN (negative-positive-negative) transistor.

7. The power switching circuit as claimed in claim 1, wherein the first switching transistor is an NMOS (n-channel enhancement mode metal-oxide-semiconductor) transistor.

8. The power switching circuit as claimed in claim 1, wherein the second switching transistor is a PMOS (p-channel enhancement mode metal-oxide-semiconductor) transistor.

9. The power switching circuit as claimed in claim 1, wherein the second switching transistor is a PNP (positive-negative-positive) transistor.

10. The power switching circuit as claimed in claim 1, wherein the third switching transistor is a PNP (positive-negative-positive) transistor.

11. The power switching circuit as claimed in claim 1, wherein the third switching transistor is a PMOS (p-channel enhancement mode metal-oxide-semiconductor) transistor.

12. The power switching circuit as claimed in claim 1, wherein the DC power supply is a five volt DC power supply.

13. The power switching circuit as claimed in claim 1, wherein the load circuit is comprised in a liquid crystal display.

14. A method of switching power via a power switching circuit comprising:
providing a control signal input terminal configured for receiving a control signal;
providing an output terminal configured to be connected to a load circuit;
providing a direct current (DC) power supply; and
providing first, second and third switching transistors; wherein
the first switching transistor and the third switching transistor are essentially directly connected to the control signal input terminal, the second switching transistor is essentially directly connected to the direct current power supply, and both the second switching transistor and the third switching transistor essentially directly connected to the output terminal while the first switching transistor is not, so that whether the output terminal receives power from the direct power supply is determined by the control signal from the control signal input terminal.
